(19) United States
(12) Patent Application Publication
(10) Pub. No.: US 2025/0273484 A1
(43) Pub. Date: Aug. 28, 2025

(54) SUBSTRATE PROCESSING APPARATUS

(71) Applicant: SAMSUNG ELECTRONICS CO., LTD., SUWON-SI (KR)

(72) Inventors: Sungjun NOH, Suwon-si (KR); Songyun KANG, Suwon-si (KR); Junho LEE, Suwon-si (KR); Jihoon JEONG, Suwon-si (KR); Young-Hoo KIM, Suwon-si (KR)

(21) Appl. No.: 18/984,335

(22) Filed: Dec. 17, 2024

(30) Foreign Application Priority Data
Feb. 22, 2024 (KR) 10-2024-0025768

(51) Int. Cl. H01L 21/67

(52) U.S. Cl. CPC H01L 21/67034

(57) ABSTRACT

A substrate processing apparatus includes a process chamber defining a process space, a first support disposed in the process space, a blocking plate supported by the first support, and a buffer extending downward from a lower surface of the blocking plate.

### CROSS-REFERENCE TO RELATED APPLICATIONS

This patent application claims priority under 35 U.S.C. § 119 to Korean Patent Application No.10-2024-0025768, filed on Feb. 22, 2024, in the Korean Intellectual Property Office, the entire contents of which are hereby incorporated by reference.

### BACKGROUND

### 1. Technical Field

The inventive concept relates to a substrate processing apparatus, and more specifically, relates to a substrate processing apparatus including a buffer coupled to a blocking plate.

### 2. Discussion of Related Art

The manufacture of a semiconductor device typically involves several processes. When processing the semiconductor device, various chemical solutions such as cleaning solutions may be used, and a drying process may be performed to remove the chemical solutions. Fluid may also be used during the drying process. An action of the fluid may cause a collapse of a semiconductor pattern of the semiconductor device, for example, due to a surface tension of the fluid. In a case that the semiconductor pattern collapses, defects may occur in the semiconductor pattern and performance of the semiconductor device may be reduced.

### SUMMARY

An object of the inventive concept is to provide a substrate processing apparatus configured to reduce eddy currents inside a process chamber.

An object of the inventive concept is to provide a substrate processing apparatus configured to inhibit collapse of a semiconductor pattern.

An object of the inventive concept is to provide a substrate processing apparatus configured to increase uniformity of a flow of a supercritical fluid on a substrate.

Objects of the inventive concept are not limited to the examples mentioned herein, and other objects not mentioned will be clearly understood by those skilled in the art from the description below.

A substrate processing apparatus according to some embodiments of the inventive concept may include a process chamber defining a process space, a first support disposed in the process space, a blocking plate supported by the first support, and a buffer extending downward from a lower surface of the blocking plate.

A substrate processing apparatus according to some embodiments of the inventive concept may include a process chamber defining a process space, a first support disposed in the process space, a blocking plate supported by the first support, a second support disposed in the process space at a position spaced upward from an upper surface of the blocking plate, and a buffer coupled to a lower surface of the blocking plate, wherein the process space includes a buffer space in which the first support and the buffer are disposed, and the blocking plate defines a thickness of the buffer space.

A substrate processing apparatus according to some embodiments of the inventive concept may include a process chamber defining a process space, a blocking plate disposed in the process space, a first support supporting the blocking plate, a second support disposed in the process space and configured to support a substrate, and a buffer coupled to a lower surface of the blocking plate, wherein the process space includes a buffer space below the blocking plate, an inner surface of the process chamber includes a first lower surface defining the buffer space, and the buffer extends from the lower surface of the blocking plate toward the first lower surface.

Specific details of embodiments are included in the detailed description and drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram showing a substrate processing apparatus according to embodiments of the inventive concept.

FIG. 2 is a perspective view showing a substrate processing apparatus according to embodiments of the inventive concept.

FIG. 3 is a cross-sectional view showing a substrate processing apparatus according to embodiments of the inventive concept.

FIG. 4 is a perspective view showing a buffer and a blocking plate according to embodiments of the inventive concept.

FIG. 5 is a cross-sectional view showing a substrate drying device according to embodiments of the inventive concept.

FIG. 6 is a cross-sectional view showing a substrate drying device according to embodiments of the inventive concept.

### DETAILED DESCRIPTION

Hereinafter, embodiments of the inventive concept will be described with reference to the attached drawings. The inventive concept may be implemented in various modifications and have various forms, and specific embodiments are illustrated in the drawings and described in detail in the text. It is to be understood, however, that the inventive concept is not intended to be limited to the particular forms disclosed, but on the contrary, is intended to cover all modifications, equivalents, and alternatives falling within the spirit and scope of the inventive concept.

The same reference numerals may refer to the same elements throughout the specification. In the drawings, the thickness, the ratio, and the dimension of the elements may be exaggerated for effective description of the technical contents.

Hereinafter, a first direction D1 and a second direction D2 may intersect each other, and a third direction D3 may cross each of the first direction D1 and the second direction D2.

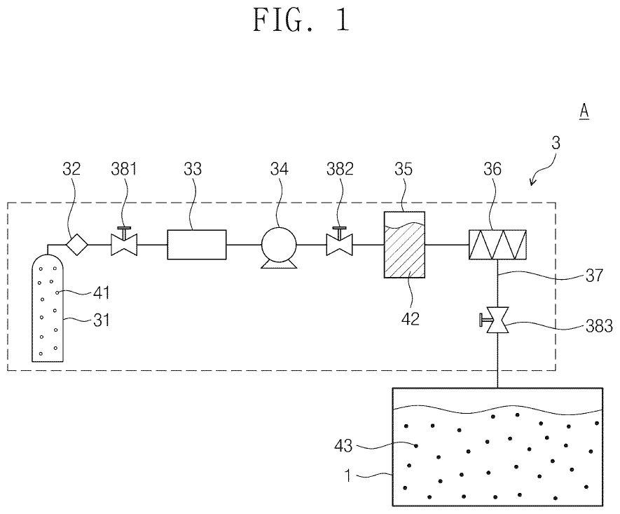

FIG. 1 is a schematic diagram showing a substrate processing apparatus according to embodiments of the inventive concept.

Referring to FIG. 1, a substrate processing apparatus A may include a fluid supplier 3 and a substrate drying device 1. The substrate drying device 1 may perform a drying process. For example, a substrate W may be disposed within the substrate drying device 1 and a drying process may be performed to dry the substrate W. In this specification, the substrate W may mean a silicon (Si) substrate. However, the inventive concept is not limited thereto. The substrate drying device 1 may be implemented in various configurations.

The fluid supplier 3 may supply fluid to the substrate drying device 1. More specifically, a drying fluid supplied by the fluid supplier 3 may be injected into the substrate drying device 1. The drying fluid supplied by the fluid supplier 3 may be carbon dioxide (CO₂). Carbon dioxide (CO₂) injected into the substrate drying device 1 may be in a supercritical fluid (SCF) state.

The fluid supplier 3 may include a fluid source 31, a fluid line 37, a supply filter 32, a first valve 381, a condenser 33, a pump 34, a second valve 382, a tank 35, a first heater 36, and a third valve 383.

The fluid source 31 may store a drying fluid. The fluid source 31 may store the drying fluid in a gaseous state 41. The fluid source 31 may supply the drying fluid. More specifically, the fluid source 31 may store and supply the drying fluid that will become a supercritical fluid. In a case where the drying fluid is CO₂, the fluid source 31 may store CO₂ in a gaseous state. The drying fluid supplied from the fluid source 31 may move along the fluid line 37.

The fluid line 37 may provide a passage through which the drying fluid supplied from the fluid source 31 flows into the substrate drying device 1. The supply filter 32 may be disposed along the fluid line 37 or at the fluid source 31 with the fluid line 37 emanating at the supply filter 32. The supply filter 32 may filter a foreign substance out of the drying fluid. The supply filter 32 may be omitted. The first valve 381 may control flow of the drying fluid by opening and closing a flow path between the fluid source 31 and the condenser 33. More particularly, the first valve 381 may control flow of the drying fluid by opening and closing a flow path between the supply filter 32 and the condenser 33.

The condenser 33 may cool the drying fluid supplied from the fluid source 31. For example, the condenser 33 may cool gaseous CO₂ supplied from the fluid source 31. Accordingly, the drying fluid in a gaseous state may be liquefied in the condenser 33. For example, a temperature of CO₂ liquefied in the condenser 33 may be about 0 degrees Celsius (° C.) to 6° C. Additionally, a pressure of CO₂ liquefied in the condenser 33 may be about 4 Megapascal (MPa) to about 6 MPa. For example, as the drying fluid is liquefied within the condenser 33, a pressure within the fluid line 37 may increase.

The pump 34 may draw the drying fluid from the fluid source 31. The pump 34 may draw the drying fluid from the condenser 33 disposed on a suction side of the pump 34. The pump 34 may increase a pressure of the drying fluid within the fluid line 37. For example, as the condenser 33 may be used to cool gaseous fluid supplied from the fluid source 31, a pressure of the drying fluid may be increased on a discharge side of the pump 34. For example, the pressure of CO₂ liquefied in the fluid line 37 on the discharge side of the pump 34 may be about 15 MPa to about 25 MPa. Additionally, a temperature of the drying fluid passing through the pump 34 may increase. For example, the temperature of CO₂ liquefied in the condenser 33 may be about 15° C. to about 25° C. as the drying fluid passes through the pump 34. The second valve 382 may control flow of the drying fluid by opening and closing a flow path between the pump 34 and the tank 35. For example, the second valve 382 may control flow of the drying fluid by restricting the flow path between the pump 34 and the tank 35. The tank 35 may store the drying fluid. The tank 35 may store the drying fluid, which has been condensed into a liquid state 42 by the condenser 33 and compressed by the pump 34.

The first heater 36 may heat the drying fluid moving along the fluid line 37. More specifically, the first heater 36 may heat CO₂ in a liquid state compressed by the pump 34. Accordingly, liquid CO₂ may become a supercritical fluid. CO₂ that is heated by the first heater 36 and reaches a supercritical state may be in a high temperature and high pressure state. For example, the temperature of CO₂ that has passed through the first heater 36 and reached a supercritical state may be about 60° C. to about 90° C. Additionally, the pressure of CO₂ that has passed through the first heater 36 and reached a supercritical state may be at a pressure of about 15 MPa to about 25 MPa. The third valve 383 may control the flow of the drying fluid that has passed through the first heater 36 and has reached a supercritical state 43. The third valve 383 may control flow of the drying fluid in a supercritical state by opening and closing a flow path between the first heater 36 and the substrate drying device 1. For example, the third valve 383 may control flow of the drying fluid in a supercritical state by restricting the flow path between the first heater 36 and the substrate drying device 1. CO₂ in a supercritical state may pass through the third valve 383 and flow into the substrate drying device 1.

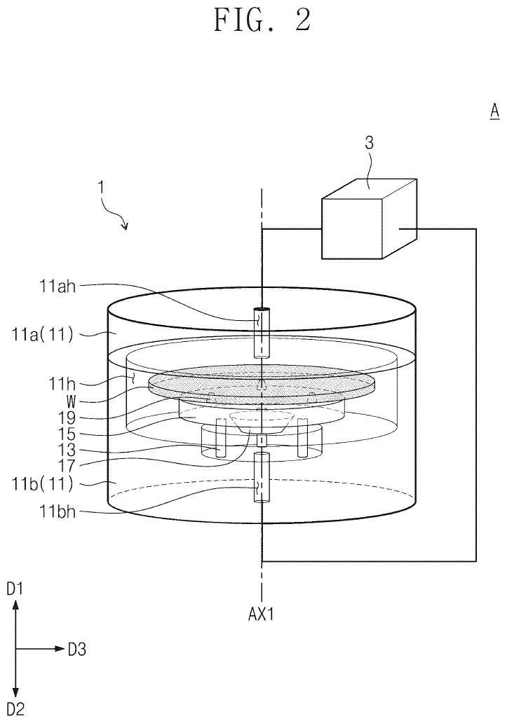

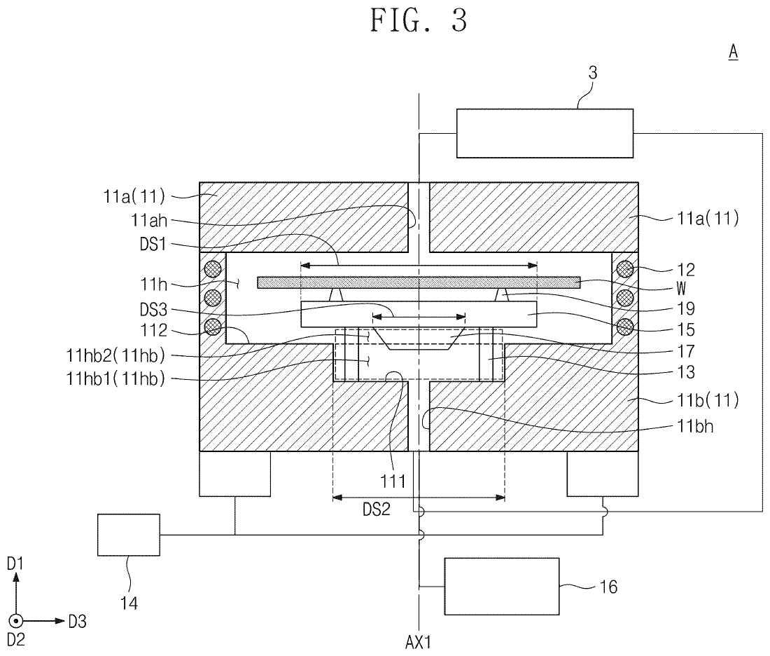

FIG. 2 is a perspective view showing the substrate processing apparatus A according to embodiments of the inventive concept. FIG. 3 is a cross-sectional view showing the substrate processing apparatus A according to embodiments of the inventive concept.

Referring to FIG. 2 and FIG. 3, the substrate drying device 1 may include a process chamber 11, a blocking plate 15, a first support 13, a second support 19, a buffer 17, a second heater 12, a chamber driving unit 14, a discharge tank 16, and a fluid supplier 3. FIG. 2 shows the substrate drying device 1 and the fluid supplier 3 for convenience.

The process chamber 11 may include a process space 11h. For example, a drying process for the substrate W may be performed in the process space 11h. The process chamber 11 may have a cylindrical shape. The process chamber 11 may have a first axis AX1 as a central axis thereof. However, a shape of the process chamber 11 is not limited thereto. The process chamber 11 may include an upper flow path 11ah connected to an upper end portion of the process space 11h. The process chamber 11 may provide a lower flow path 11bh connected to a lower end portion of the process space 11h. The upper flow path 11ah and the lower flow path 11bh may be connected to the process space 11h. For example, the upper flow path 11ah and the lower flow path 11bh may be disposed at opposite ends of the process space 11h. The upper flow path 11ah may be connected to the fluid supplier 3. The lower flow path 11bh may be connected to the fluid supplier 3. Fluid may flow into the process space 11h through the upper flow path 11ah and the lower flow path 11bh. The lower flow path 11bh may also be connected to the discharge tank 16. The fluid in the process space 11h may be discharged to the discharge tank 16 through the lower flow path 11bh. The process chamber 11 may include a lower portion 11b and an upper portion 11a. A process space 11h may be provided between the lower portion 11b and the upper portion 11a. The lower portion 11b may be disposed below from the upper portion 11a. The lower portion 11b may move up and down (vertically). For example, the lower portion 11b may be moved upward by operation of the chamber driving unit 14 and combined with the upper portion 11a. However, a combination of the upper portion 11a and the lower portion 11b is not limited thereto. The upper portion 11a may move up and down by operation of the chamber driving unit 14. The upper portion 11a may be moved up and down by the chamber driving unit 14 and combined with the lower portion 11b. The lower portion 11b and the upper portion 11a may be combined to isolate the process space 11h from the outside. The upper portion 11a may include an upper flow path 11ah. The lower portion 11b may include a lower flow path 11bh. The process space 11h may include a buffer space 11hb.

The blocking plate 15 may be disposed in the process space 11h. The blocking plate 15 may have a rectangular parallelepiped shape. However, a shape of the blocking plate 15 is not limited thereto.

The blocking plate 15 may be configured to support the substrate W. The blocking plate 15 may protect the lower surface of the substrate W from fluid flowing into the process chamber 11 through the lower flow path 11bh. The blocking plate 15 may inhibit or prevent the fluid flowing into the lower flow path 11bh from being directly sprayed onto the substrate W.

The blocking plate 15 may be supported by the first support 13. The first support 13 extend from an outer portion of a lower surface of the blocking plate 15. The first support 13 may be disposed in the process space 11h. The first support 13 may be disposed in the buffer space 11hb. A plurality of first supports 13 may be provided. For example, the plurality of first supports 13 may be arranged in a pattern around the outer portion of the lower surface of the blocking plate 15. Hereinafter, for convenience, the plurality of first supports 13 may be treated and described as a singular component.

An area of the blocking plate 15 may be smaller than the area of the substrate W. More specifically, a diameter DS1 of the blocking plate 15 may be about 300 millimeters (mm) or less. The diameter DS1 of the blocking plate 15 may be larger than a diameter DS2 of the buffer space 11hb. A diameter of an upper surface of the buffer 17 may be less than the diameter of the blocking plate 15.

The buffer space 11hb may be defined by a first lower surface 111 of the process chamber 11. An inner surface of the process chamber 11 may include the first lower surface 111 and a second lower surface 112. A level of the first lower surface 111 may be lower than a level of the second lower surface 112. The buffer space 11hb may include a first space 11hb1 and a second space 11hb2.

The first space 11hb1 may be a recessed portion of the buffer space 11hb formed in the process space 11h. For example, the first space 11hb1 may be a recessed space formed in the lower portion 11b of the process chamber 11. The first space 11hb1 may be defined by the first lower surface 111. For example, a height of the first space 11hb1 may be the same as a height at the recessed portion of the buffer space 11hb formed in the process space 11h.

The second space 11hb2 may be defined on the first space 11hb1. The second space 11hb2 may be a space defined below the blocking plate 15 from an upper end of the first space 11hb1.

The blocking plate 15 may be disposed above the buffer space 11hb. A lower end portion of the first support 13 may be disposed in the first space 11hb1. The first support 13 may extend from the first lower surface 111 to the lower surface of the blocking plate 15. The first support 13 may be disposed in the buffer space 11hb.

The buffer 17 may improve a uniformity of the fluid flow. The buffer 17 may be disposed in the buffer space 11hb. The buffer 17 may extend downward from the lower surface of the blocking plate 15. The buffer 17 may be disposed at a central portion on the lower surface of the blocking plate 15. The buffer 17 may extend from the lower surface of the blocking plate 15 toward the first lower surface 111. The area of the upper surface of the buffer 17 may be greater than the area of the lower surface of the buffer 17.

A space in which fluid moves in the buffer space 11hb may be variously changed depending on the buffer 17. For example, the space may be reduced when a size of the buffer 17 is increased, or the space may be increased when a size of the buffer 17 is decreased.

The buffer 17 may be integrally coupled to the blocking plate 15. However, a coupling relationship between the buffer 17 and the blocking plate 15 is not limited thereto. The buffer 17 may be a separate component from the blocking plate 15, and may be detachable from, and attachable to the blocking plate 15. The area of the upper surface of the buffer 17 may be smaller than the area of the lower surface of the blocking plate 15.

A diameter DS3 of an upper surface of the buffer 17 may be smaller than the diameter DS2 of the buffer space 11hb. For example, the diameter DS3 of the upper surface of the buffer 17 may be about 30% to about 60% of the diameter DS2 of the buffer space 11hb. However, the diameter DS3 of the upper surface of the buffer 17 is not limited thereto. In a case that the diameter DS3 of the upper surface of the buffer 17 is smaller than the diameter DS1 of the blocking plate 15 and the diameter DS2 of the buffer space 11hb, a rate of the fluid flow from the lower flow path 11bh may be decreased.

In a case that the area of the upper surface of the buffer 17 is greater than the area of the lower surface of the buffer 17, a height of the buffer space 11hb increases away from the first axis AX1 of the process chamber 11. More specifically, when the fluid flowing in from the lower flow path 11bh collides with the buffer 17 and flows toward the first support 13, the buffer space 11hb through which the fluid moves may have an increasing height and the fluid movement rate may decrease. For example, the buffer space 11hb through which the fluid moves may expand away from the first axis AX1 and the fluid movement rate may decrease.

A thickness of the buffer 17 may be smaller than a thickness of the buffer space 11hb. For example, a thickness of the buffer 17 may be about 60% or less of a thickness of the buffer space 11hb. The thickness of the buffer space 11hb may refer to a distance from the first lower surface 111 to the lower surface of the blocking plate 15. For example, the blocking plate 15 may define a thickness of the buffer space 11hb. However, the thickness of the buffer 17 is not limited thereto.

The second support 19 may be disposed in the process space 11h. The second support 19 may support the substrate W. The second support 19 may place the substrate W at a position spaced upward from the blocking plate 15. The second support 19 may extend upward from the upper surface of the blocking plate 15. In other words, a level of an upper end portion of the second support 19 may be higher than a level of an upper surface of the blocking plate 15. A level of a lower surface of the second support 19 may be higher than a level of a lower surface of the blocking plate 15. A plurality of second supports 19 may be provided. For example, the plurality of second supports 19 may be arranged in a pattern on the upper surface of the blocking plate 15. Hereinafter, for convenience, the plurality of second supports 19 will be treated and described as a singular component. A height of the second support 19 in the first direction D1 may be less than a height of the first support 13 in the first direction D1.

The second heater 12 may be disposed in the process chamber 11. The second heater 12 may be thermally coupled to the process chamber 11. The second heater 12 may heat the process space 11h. By heating the process space 11h, the fluid flowing into the process space 11h may be maintained in a supercritical state.

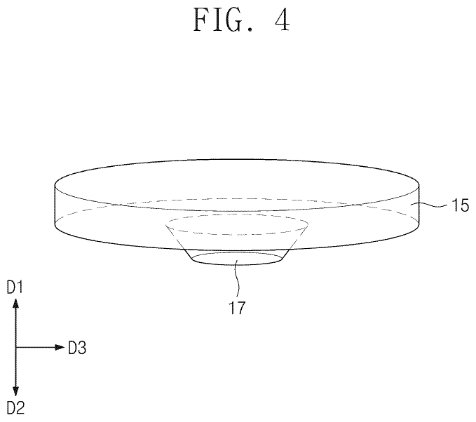

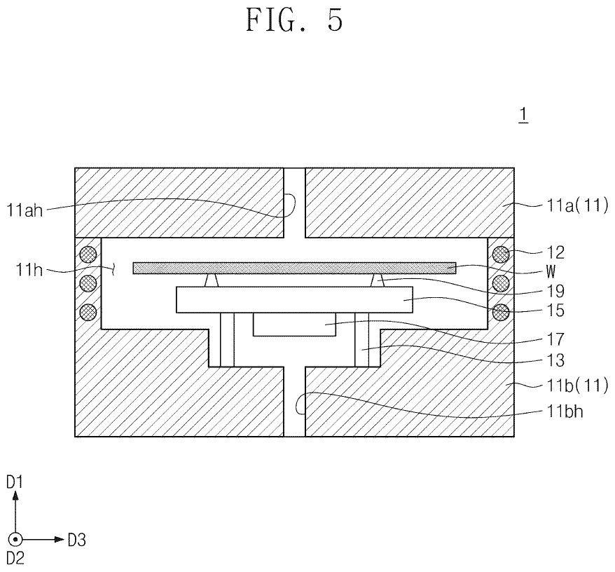

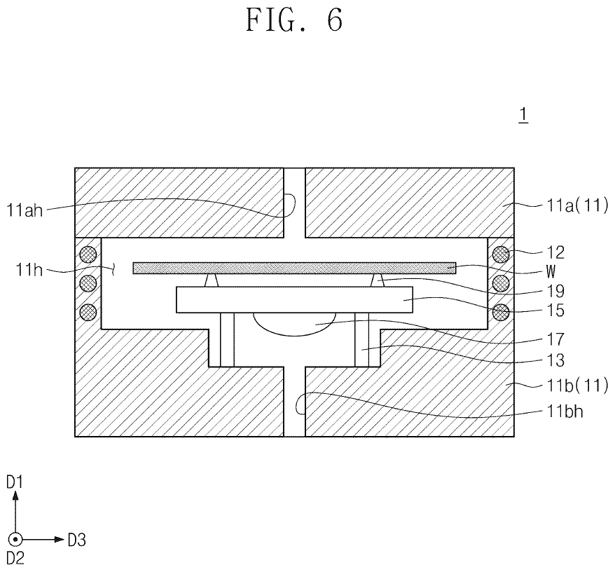

FIG. 4 is a perspective view showing the buffer 17 and the blocking plate 15 according to embodiments of the inventive concept. FIG. 5 is a cross-sectional view showing the substrate drying device 1 according to embodiments of the inventive concept. FIG. 6 is a cross-sectional view showing the substrate drying device 1 according to embodiments of the invention.

Referring to FIG. 4, the area of a lower surface of the buffer 17 may be smaller than the area of an upper surface of the buffer 17. The lower surface of the buffer 17 and the upper surface of the buffer 17 may be connected to a side surface of the buffer 17. The lower surface of the buffer 17 and the upper surface of the buffer 17 may be connected to each other by the side surface of the buffer 17. An angle formed between the side surface of the buffer 17 and the lower surface of the blocking plate 15 may be about 60 degrees or less. A shape of the buffer 17 is not limited thereto. For example, referring to FIG. 5, the buffer 17 may have a rectangular parallelepiped shape. Referring to FIG. 6, an outer surface of the buffer 17 may include a curved surface. The buffer 17 may have a hemispherical shape. However, the shape of the buffer 17 is not limited to the shape of FIG. 4, FIG. 5, and FIG. 6. For example, the buffer 17 may have a concave shape. The buffer 17 may have a different shape that may reduce flow rate of the fluid when the fluid flows into the buffer space 11hb.

According to the substrate processing apparatus according to embodiments of the inventive concept, flow uniformity of the fluid flowing on an upper surface of the substrate may be increased. In the case that the buffer is coupled to the lower surface of the blocking plate, a volume of space through which fluid moves may increase away from a center portion of the process chamber 11. The height of the space at the center portion of the process chamber 11 may be different from the height of the space in which the fluid moves outside the buffer space. For example, the volume of the space may have a cross section that increase as the fluid moves from the center portion of the process chamber to outside the buffer space. As the fluid moves from inside the buffer space to outside the buffer space, a volume of the space in which the fluid moves may increase. As the volume of space in which the fluid moves increases, the flow rate of the fluid may decrease as the fluid moves from the center portion of the buffer space to outside the buffer space. The first support may inhibit the flow rate of the fluid, and the flow rate of the fluid may decrease. For example, as the fluid collides with the first support, the fluid flow rate may be slowed and eddy currents in the fluid may be decreased. By reducing eddy currents in the fluid occur, the flow of fluid on the substrate may become more uniform. Further, by reducing eddy currents in the fluid, stress may be on the semiconductor pattern may be reduced. As the flow rate of the fluid is reduced by the buffer, a collapse of the semiconductor pattern and deterioration of quality due to the fluid may be inhibited or prevented.

According to the substrate processing apparatus of the inventive concept, an eddy current inside the process chamber may be reduced or prevented.

According to the substrate processing apparatus of the inventive concept, the collapse of the semiconductor pattern may be inhibited or prevented.

According to the substrate processing apparatus of the inventive concept, flow uniformity of the supercritical fluid on the substrate may be increased.

Effects of the inventive concept are not limited to the effects mentioned herein, and other effects not mentioned will be clearly understood by those skilled in the art from the description below.

While embodiments are described above, a person skilled in the art may understand that many modifications and variations are made without departing from the spirit and scope of the inventive concept defined in the following claims. Accordingly, example embodiments of the inventive concept should be considered in all respects as illustrative and not restrictive, with the spirit and scope of the inventive concept being indicated by the appended claims.

What is claimed is:

1. A substrate processing apparatus comprising:
a process chamber defining a process space;
a first support disposed in the process space;
a blocking plate supported by the first support; and
a buffer extending downward from a lower surface of the blocking plate.

2. The substrate processing apparatus of claim 1, wherein the process space includes a buffer space defined below the blocking plate,
wherein the buffer space includes:
a first space in which a lower end portion of the first support is disposed on the process chamber; and
a second space on the first space,
wherein the buffer is disposed in the buffer space.

3. The substrate processing apparatus of claim 2, wherein a diameter of an upper surface of the buffer is about 30% to about 60% of a diameter of the buffer space.

4. The substrate processing apparatus of claim 2, wherein a thickness of the buffer is about 60% or less of a thickness of the buffer space.

5. The substrate processing apparatus of claim 1, wherein the process chamber includes:
an upper flow path connected to an upper end portion of the process space; and
a lower flow path connected to a lower end portion of the process space.

6. The substrate processing apparatus of claim 1, wherein the buffer is disposed at a center portion of the blocking plate, and
wherein the first support extends downward from the lower surface of the blocking plate and disposed at an outer portion of the blocking plate.

7. The substrate processing apparatus of claim 1, further comprising a second support disposed in the process space and configured to support a substrate,
wherein the second support is disposed a position spaced upward from an upper surface of the blocking plate.

8. The substrate processing apparatus of claim 1, further comprising a second support disposed in the process space and configured to support a substrate,
wherein the second support extends upward from an upper surface of the blocking plate.

9. The substrate processing apparatus of claim 1, wherein an area of a lower surface of the buffer is smaller than an area of an upper surface of the buffer,
wherein the lower surface of the buffer and the upper surface of the buffer are connected to a side surface of the buffer, and
wherein an angle formed between the side surface of the buffer and the lower surface of the blocking plate is about 60 degrees or less.

10. The substrate processing apparatus of claim 1, wherein the buffer has a rectangular parallelepiped shape.

11. The substrate processing apparatus of claim 1, wherein an outer surface of the buffer includes a curved surface.

12. The substrate processing apparatus of claim 1, wherein the blocking plate has a diameter of about 300 millimeters or less, and a diameter of an upper surface of the buffer is less than the diameter of the blocking plate.

13. A substrate processing apparatus comprising:
a process chamber defining a process space;
a first support disposed in the process space;
a blocking plate supported by the first support;
a second support disposed in the process space at a position spaced upward from an upper surface of the blocking plate; and
a buffer coupled to a lower surface of the blocking plate,
wherein the process space includes a buffer space in which the first support and the buffer are disposed, and
wherein the blocking plate defines a thickness of the buffer space.

14. The substrate processing apparatus of claim 13, wherein a diameter of the blocking plate is greater than a diameter of the buffer space, and
wherein a diameter of an upper surface of the buffer is about 30% to about 60% of a diameter of the buffer space.

15. The substrate processing apparatus of claim 13, wherein a thickness of the buffer is about 60% or less of a thickness of the buffer space.

16. The substrate processing apparatus of claim 13, wherein the second support extends upward from the upper surface of the blocking plate and is configured to support a substrate.

17. A substrate processing apparatus comprising:
a process chamber defining a process space;
a blocking plate disposed in the process space;
a first support supporting the blocking plate;
a second support disposed in the process space and configured to support a substrate; and
a buffer coupled to a lower surface of the blocking plate,
wherein the process space includes a buffer space below the blocking plate,
wherein an inner surface of the process chamber includes a first lower surface defining the buffer space, and
wherein the buffer extends from the lower surface of the blocking plate toward the first lower surface.

18. The substrate processing apparatus of claim 17, wherein an area of an upper surface of the buffer is smaller than an area of the lower surface of the blocking plate.

19. The substrate processing apparatus of claim 17, wherein the first support and the buffer are disposed in the buffer space.

20. The substrate processing apparatus of claim 17, wherein a diameter of an upper surface of the buffer is about 30% to about 60% of a diameter of the buffer space, and wherein a thickness of the buffer is about 60% or less of a thickness of the buffer space.
